(19) United States
(12) Patent Application Publication
(10) Pub. No.: US 2026/0088118 A1
(43) Pub. Date: Mar. 26, 2026

(54) ENHANCED TRAINING FOR DUTY CYCLE ADJUSTER (DCA) TO MINIMIZE JITTER IN DRAM TRANSMITTER SIGNALS

(71) Applicant: Tektronix, Inc., Beaverton, OR (US)

(72) Inventors: Swapnil Jhawar, Bengaluru (IN); Chandra Sekhar Kappagantu, Bengaluru (IN); Aiswarya Prasad, Bengaluru (IN)

(21) Appl. No.: 19/333,112

(22) Filed: Sep. 18, 2025

(30) Foreign Application Priority Data
Sep. 20, 2024 (IN) 202421071198

(51) Int. Cl. G11C 29/12; G11C 11/4076

(52) U.S. Cl. CPC G11C 29/12015; G11C 11/4076

(57) ABSTRACT

A test and measurement instrument includes one or more test channels to connect to a memory device under test (DUT) and analyze signals generated by the DUT, and one or more processors configured to execute code to cause the DUT to generate strobe and data signals using a first clock setting of the DUT, determine whether the period of the strobe signal and data signals are within a tolerance specification, and perform at least one additional measurement of the DUT when the period of the strobe and data signals are within the tolerance specification. Methods are also described.

### CROSS-REFERENCE TO RELATED APPLICATIONS

This disclosure claims priority under 35 U.S.C. § 119 to Indian Provisional Patent Application No. 202421071198, titled “ENHANCED TRAINING ALGORITHM FOR DUTY CYCLE ADJUSTER (DCA) TO MINIMIZE JITTER IN DDR5 DRAM TRANSMITTER SIGNALS,” filed on Sep. 20, 2024, the disclosure of which is incorporated herein by reference in its entirety.

### TECHNICAL FIELD

The present disclosure relates to duty cycle adjuster (DCA) training operations. In particular, the present disclosure relates to a methodology for duty cycle adjuster (DCA) training operation to minimize jitter associated with DDR5 DRAM transmitters and with other transmitters, including future transmitters, that use DCA training operations.

### BACKGROUND

DDR is an acronym for double data rate, which describes a memory technology based on Synchronous dynamic random-access memory (SDRAM). DDR SDRAM access is twice as fast as SDRAM, because DDR data transfer occurs on both rising and falling edges of the clock signal as compared to SDRAM, which transfers data only on the rising edge of a clock. FIG. 1 illustrates the concept of double data rate data transfer. As illustrated in FIG. 1, a DDR memory device 10 is capable of transmitting data from the memory to a memory controller or other device reading the data on every rising edge and every falling edge of a clock pulse. In FIG. 1, the data transfers are illustrated with the solid dots, with one data transfer on each rising edge and each falling edge. Since each clock cycle includes both a rising clock edge and a falling clock edge, DDR devices transmit data twice for each clock cycle, which is twice the data transfer rate of SDRAM.

Conforming DDR memory modules are those that satisfy the DDR5 SDRAM standard developed by the Joint Electron Devices Engineering Council (JEDEC) Solid State Technology Association. According to this standard, a DDR interface allows each DRAM chip to transfer data to/from the memory controller by means of multiple digital data lines. These data streams are accompanied by a strobe signal, as data can flow both from the controller to the DRAM (write operation) and from the DRAM to the controller (read operation). These digital lines are bi-directional in nature. The DDR command bus consists of multiple signals that control the operation of the DDR interface. DDR5 DRAM is fifth-generation double data rate (DDR) dynamic random-access memory (DRAM) technology, although embodiments of this disclosure are applicable to any future memory that uses the same or similar DCA training described herein.

The JEDEC standard for DDR5 DRAM directs that the duty cycle of Strobe (DQS) and Data (DQ) signals within a DDR memory get adjusted as close to 50% as possible prior to performing a series of tests, including DQS Jitter, DQ Jitter and Data Stressed Eye tests. DDR5 DRAM supports a mode register adjustable Duty Cycle Adjuster (DCA) to allow the memory controller to adjust the DRAM internally generated DQS clock tree and DQ duty cycle to compensate for duty cycle error of all DQS and DQ signals. For DDR5, the DQS clock tree is internally generated by using a multi-phase clock(s). In the case of DQS clock tree using a 4-phase internal clocks, the DDR5 specification defines the phases as: ICLK (0°); QCLK (90°); IBCLK (180°); and QBCLK (270°). As described in the JEDEC specification, the memory controller can adjust the duty cycles for the clock phases for DQS by setting applicable DCA code values in the DCA mode registers MR43 (QCLK & IBCLK) and MR44 (QBCLK).

In DDR5 DRAM interfaces, the 4-phase internal clocks play crucial roles in coordinating the transfer of data between the memory controller and the memory device. Each clock signal serves a specific purpose and ensures the proper timing and synchronization of data transmission.

A Quarter Clock signal (QCLK) operates at one-quarter of the frequency of the data transfer rate. QCLK provides timing references for the internal operations within the memory device, including data sampling and signal processing. QCLK helps in synchronizing the internal operations with the external data transactions, ensuring dependable data transfer.

An Input Burst Clock signal (IBCLK) is an internal clock signal used for coordinating the input burst operation within the memory device. When data is being written into the memory device, IBCLK controls the timing of the input data bursts, ensuring that the data is sampled and latched correctly. This clock helps in maintaining the integrity and accuracy of the data being written into the memory.

A Quarter Burst Clock signal (QBCLK) is a clock signal that operates at one-quarter of the frequency of the burst data transfer rate. Like QCLK, QBCLK provides timing references for internal operations within the memory device, specifically during burst data transfers. This clock ensures that the data bursts are properly aligned and synchronized with the internal operations, minimizing any potential timing errors.

An Input Clock (ICLK) is the primary clock signal that controls the overall timing of data input operations in the memory device. This clock synchronizes the arrival of input data with the internal clock domain of the memory device, ensuring that the incoming data is sampled and processed accurately. ICLK plays a vital role in coordinating the data transfer between the memory controller and the memory device.

Together, these 4-phase internal clocks-QCLK, IBCLK, QBCLK, and ICLK-work in tandem to ensure the proper timing, synchronization, and integrity of data transfer operations within DDR5 DRAM interfaces.

As mentioned above, the JEDEC specification directs that the duty cycle of Strobe (DQS) and Data (DQ) signals within a DDR memory get adjusted as close to 50% as possible prior to performing subsequent qualification tests on the DRAM. One problem with adjusting these duty cycles, which is referred to herein as Duty Cycle Adjusting (DCA), is that present methods take significant time, measured in 10s of minutes, to properly determine the best DCA settings for a particular DDR module. Since manufacturers or other DRAM device users test each individual memory module prior to qualifying the DRAM as compliant, the long time necessary to determine the best DCA settings using conventional methods poses significant problems.

### BRIEF DESCRIPTION OF THE DRAWINGS

FIG. 1 is a timing diagram that illustrates conventional double data rate (DDR) data transfer.

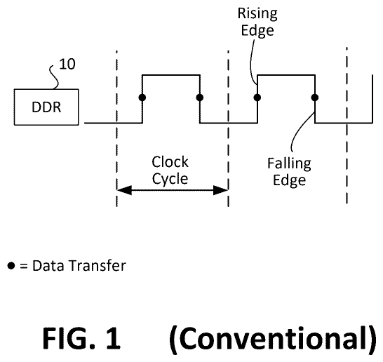

FIG. 2 is a block system diagram illustrating a DDR test platform including a Memory Device Under Test (DUT) test fixture connected to a number of test and measurement instruments structured to perform duty cycle adjuster (DCA) adjustments according to an exemplary implementation of the disclosure.

FIG. 3 is a clock cycle timing diagram that illustrates odd and even cycles in a clock signal according to an exemplary implementation of the disclosure.

FIG. 4 is a flowchart showing example operations for DCA training according to an exemplary implementation of the disclosure.

FIG. 5 is an Eye Diagram illustrating output from a DDR memory operating without the DCA methodology described herein.

FIG. 6 is an Eye Diagram illustrating output from a DDR memory operating after the DCA methodology described herein has been applied.

### DETAILED DESCRIPTION

The various embodiments of the present disclosure relate to enhanced training operations for a Duty Cycle Adjuster (DCA) to minimize jitter in dynamic random-access memory (DRAM) transmitter signals. Although described with reference to firth-generation (DDR5) DRAM modules, embodiments of the invention are applicable to any DRAM modules, even future modules, that use DCA adjustment in the same or similar manner as described herein.

The present disclosure provides a novel methodology for DCA training operations and procedures to minimize jitter associated with DRAM transmitters. DCA training reduces duty cycle error and hence reduce phase mismatch-translated jitter in the transmitter Strobe (DQS) and Data (DQ) signals. This reduced duty cycle error significantly enhances the Eye parameters of Data signals read from the DRAM module, leading to improved data transmission reliability and performance.

DDR5 DRAM supports a mode register adjustable DCA to allow the memory controller to adjust the DRAM internally generated DQS clock tree and DQ duty cycle to compensate for duty cycle error of all DQS and DQ signals. Various methodologies were proposed to determine the optimum DCA mode register settings.

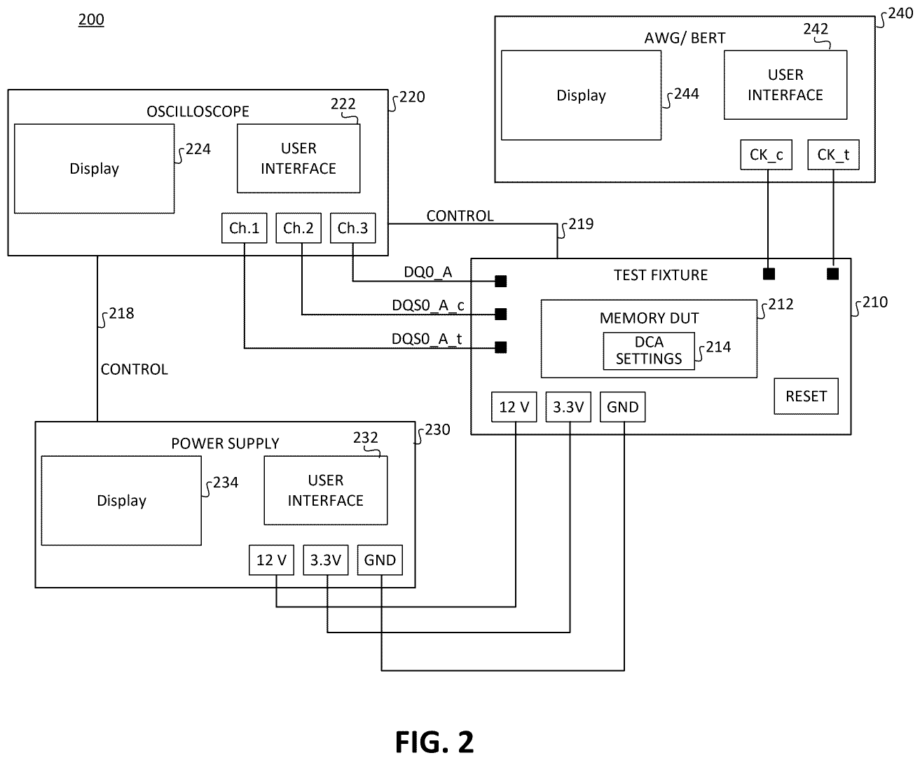

The strobe and data signal analysis of the DCA methodology described herein may operate on a testing platform, such as a testing platform 200 illustrated in FIG. 2. A Memory Device Under Test (Memory DUT) 212, or DUT, may be a logical unit of memory storage, such as a Dual In-Line Memory Module (DIMM) mounted in a test fixture 210, which may be a Channel Test Card 2 (CTC2) fixture available from Astek Corporation. In general, several components of the testing platform 200 connect to the test fixture 210 to provide power and control signals that cause the Memory DUT 212 to generate strobe and data signals for evaluation.

A power supply 230 may include a user interface 232 as well as a display 234 that shows operating parameters of the power supply. The power supply 230 provides power at the appropriate voltages, such as 12 Volts and 3.3 Volts to the test fixture 210. A ground reference is also supplied to the test fixture 210.

A clock generator 240 that is connected to the test fixture 210 also includes a user interface 242 and a display 244 that informs users about the operation of the clock generator 240. In some embodiments the clock generator 240 is either an Arbitrary Waveform Generator (AWG) or a Bit Error Ratio Tester (BERT). In operation, the clock generator 240 generates clock signals used by the test fixture 210 in testing the Memory DUT 212 as described in further detail below.

Finally, a test and measurement device, such as an oscilloscope 220, couples to the test fixture 210. Although embodiments of the disclosure are described with reference to an oscilloscope as the test and measurement device in the testing platform 200, any test and measurement device that can control the test fixture 210 and measure the signals generated by the Memory DUT 212 may be used, and this disclosure is not limited to oscilloscopes but rather includes any device capable of performing the operations described herein. The oscilloscope 220 receives strobe and data signals on individual channels of the oscilloscope for analysis. For example, a DQS signal for a particular data channel (Data channel 0) may be received at Channel 1 of the oscilloscope 220, while the DQS complement signal for the same data channel 0 is received at Channel 2. A data signal DQ for the particular channel is received at Channel 3 of the oscilloscope 220. A user may perform testing of the Memory DUT 212 using a user interface 222 of the oscilloscope 220 and viewing results on a display 224. In operation, the oscilloscope 220 operates as directed by the user. For example, the user may direct that the oscilloscope 220 perform DCA analysis on the Memory DUT 212 by selecting the analysis from a menu or by using particular keyboard commands. In response, the oscilloscope 220 sends control signals through control lines 218, 219 to the power supply 230 and the test fixture 210, respectively, to cause the Memory Dut 212 to generate output based on the control signals. Then the output from the Memory Dut 212 is analyzed by the oscilloscope 220. Based on this analysis, the oscilloscope 220 writes particular DCA values into a DCA settings register 214, described above, of the Memory DUT 212, which causes the Memory Dut 212 to operate with clock signals within a specified value of precision. Then the Memory Dut 212 may be tested for DQS Jitter, DQ Jitter, and Data Stressed Eye tests according to the Joint Electron Devices Engineering Council (JEDEC) Standard to determine whether the Memory DUT conforms to the standard.

In more detail, after the oscilloscope 220 acquires strobe (DQS) and data (DQ) signals from the Memory DUT 212, the oscilloscope iterates on these signals over the possible combinations of Input Burst Clock signal (IBCLK), Quarter Clock signal (QCLK) and Quarter Burst Clock signal (QBCLK) values using period and duty cycle measurements, which are described in more detail below. After the various combinations of IBCLK, QCLK and QBCLK values are analyzed, the oscilloscope 220 determines the optimal mode register configurations to reduce duty cycle error and jitter for DQ and DQS signals, and configures the DCA settings 214 accordingly. The operations described below for determining the DCA settings occur much faster than conventional DCA operations, resulting in reduced signal jitter and improved efficiency and accuracy of validation of the Memory DUT 212.

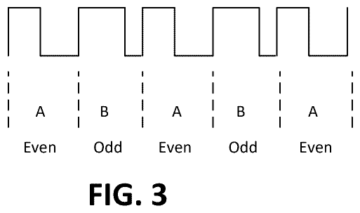

Embodiments described herein use period and duty cycle measurements on ODD and EVEN cycles of a DRAM clock to determine the DCA optimal mode register settings. As illustrated in FIG. 3, an even cycle of a DRAM clock has a 50% duty cycle, while an odd cycle of a DRAM clock does not have a 50% duty cycle. An even and odd Cycle in a clock signal refers to the time period between two consecutive rising edges. An even cycle occurs on every even count of the clock signal and an odd cycle occurs on every odd count of the clock signal. In FIG. 3, the even duty cycles are labeled as “A”, while odd duty cycles are labeled as “B”. Both even and odd duty cycles are used in embodiments, as described in greater detail below.

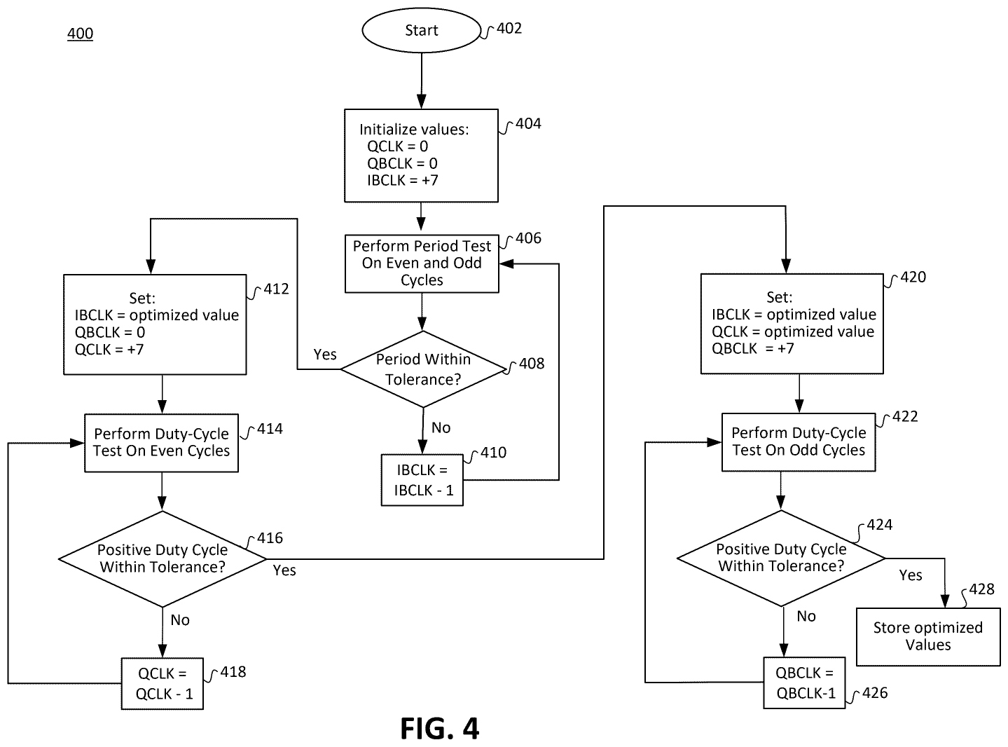

FIG. 4 is a flowchart showing example flow 400 of operations for DCA training according to an exemplary implementation of the disclosure. In particular, the flow 400 determines DCA code values for adjusting QCLK, QBCLK, and IBCLK so that further testing and qualification of the Memory DUT 212 (FIG. 2) may be performed.

A user of the oscilloscope 220 (FIG. 2), or other test and measurement instrument, initiates the DCA analysis described in the 400 in an operation 402. As described above, the user may select the DCA analysis from a menu or by sending appropriate commands to the oscilloscope 220. Clock values for QCLK and QBCLK are initialized to zero, and IBCLK is initialized to +7, which is the largest value possible for IBCLK adjustment, in an operation 404.

In general, during an initial phase of DCA training as illustrated by operations 404-410, the flow 400 determines the optimal step value for IBCLK with both QCLK and QBCLK set to 0. Within this phase, IBCLK is incrementally adjusted from +7 to −7. For each increment, the periods for both even and odd cycles of the differential DQS signal are calculated. The first IBCLK value that produces differential DQS signal with periods falling within the tolerance range specified by the data rate is chosen as the optimized IBCLK value.

More specifically, operation 406 performs a period test on both even and odd cycles, described with reference to FIG. 3 above. Period Measurement is defined as the elapsed time between consecutive crossings of the mid reference voltage level in the direction specified. The first time through the period test in the operation 406, the IBCLK is set to the initialized value of +7. Then an operation 408 determines if the results of the period test generated in operation 406 are within the tolerance range, such as 1% tolerance. If not, the IBCLK value is decremented by 1 in an operation 410 and the flow 400 loops back to again perform period tests on both even and odd cycles in operation 406. This loop repeats until the period test in operation 406 produces results that are within the specified tolerance of operation 408, which, in this example, is 1%, although other tolerance values could be chosen. In some embodiments the value for IBCLK could be initialized to −7 in the operation 404 and the operation 410 increments, rather than decrements, the IBCLK value.

Following the optimization of IBCLK, as described above, the second phase of the flow 400 focuses on obtaining an optimized value of QCLK with operations 412-418. Within this second phase, QCLK is varied from +7 to −7 while holding the optimized IBCLK value constant and setting QBCLK to 0. For each increment, the positive duty cycle of even cycles is measured for a differential DQS signal. The first QCLK value that generates a signal with a positive duty cycle for even cycles within a 1% deviation from the ideal value of 50% is selected as the optimized QCLK value.

More specifically, operation 412 sets the IBCLK value to the value determined in the operations 404-410, i.e. the value that satisfies the tolerance test of operation 408. Then the operation 412 sets the QBCLK to 0 and initializes the QCLK to +7. Then an operation 414 performs a duty-cycle test on the even cycles using the initialized value for QCLK. Positive duty cycle Measurement is defined as the proportion of time within a periodic signal during which the signal is in the “high” state relative to the total period of the signal according to Equation (1).

$$Duty Cycle Positive = \frac{{t}_{high}}{T} \times 100 \% \qquad Eq . ( 1 )$$

where t-high is the duration of the high state, and T is period of the signal.

Next an operation 416 determines whether the duty-cycle tests generated in operation 414 are within the tolerance range, such as 1% tolerance. If not, the QCLK value is decremented by 1 in an operation 418 and the flow 400 loops back to again perform duty cycle testing on the even cycles in the operation 414 using the new value for QCLK. This loop of operations 414-418 repeats until the duty-cycle tests generated in operation 414 produces results that are within the specified tolerance of operation 416, which, in this example, is 1%, although other tolerance values could be chosen. Again, similar to the discussion above, the QCLK value in operation 412 could be set to −7 and subsequently incremented in the operation 418, rather than starting at +7 and decrementing.

In the subsequent third phase, the optimization process targets QBCLK. The steps range from +7 to −7 while maintaining the optimized values of IBCLK and QCLK. During each increment, the positive duty cycle of odd cycles for the differential DQS signal is measured. The first QBCLK value that produces a signal with a positive duty cycle for odd cycles within a 1% deviation from the ideal value of 50% is selected as the optimized QBCLK value.

Again, in more detail, an operation 420 sets IBCLK and QCLK to their optimized values determined in operations 408 and 416, respectively, and initializes QBCLK to +7. Next, operation 422 performs duty-cycle testing on odd cycles, rather than the even cycles tested in operation 414. If the duty-cycle testing of operation 422 is within the tolerance range, such as 1%, then the operation 424 is exited in the YES direction, and the optimized values for IBCLK, QCLK, and QBCLK are stored in an operation 428. If the particular QBCLK value used in operation 422 did not produce testing within the desired tolerance value, then it is decremented in an operation 426 and the flow 400 loops back to operation 422, where the odd cycle duty-cycle testing is performed with the new value for QBCLK.

Although in the flow 400 the optimized value for QCLK is set in operation 416, which appears in FIG. 4 prior to setting the optimized value for QBCLK in operation 424, in practice either the QCLK or the QBCLK may be optimized in either order. According to embodiments, the optimization of IBCLK precedes both the optimization of QCLK or QBCLK, which, again, can occur in any order.

The DCA training description above with reference to the flow 400 and optimizing values for IBCLK, QCLK and QBCLK first occurs for the DQS signals from the Memory DUT 212 (FIG. 2), and is then repeated for DQ signals to further qualify the Memory DUT. DCA training on DQ signals is performed similar to the flow 400 described above for DQS signals, except that per-pin DCA mode registers of DQ are used to change the step sizes of IBCLK, QCLK and QBCLK from +3 to −3, instead of +7 to −7, with the global DCA mode registers programmed with the optimized value of IBCLK, QCLK and QBCLK obtained in the previous steps of DCA training for the DQS signal.

Referring back to FIG. 2, after the flow 400 has been executed to determine the IBCLK, QCLK, and QBCLK signals for both the DQS signal as well as the DQ signals, the oscilloscope 220, or other component of the testing platform 200 writes the clock settings into the appropriate DCA settings register 214 of the Memory Dut 212. Then the DQS Jitter, DQ Jitter, and Data Stressed Eye tests using data generated by the Memory DUT 212 having the appropriate DCA settings can be executed by the oscilloscope 220 in conjunction with other components of the testing platform 200.

The proposed method allows for more predictable and reliable products, ensuring that the Memory DUT meets quality standards. The methods described herein enable the user to extract DCA code setting values found using the operations described with reference to FIG. 4.

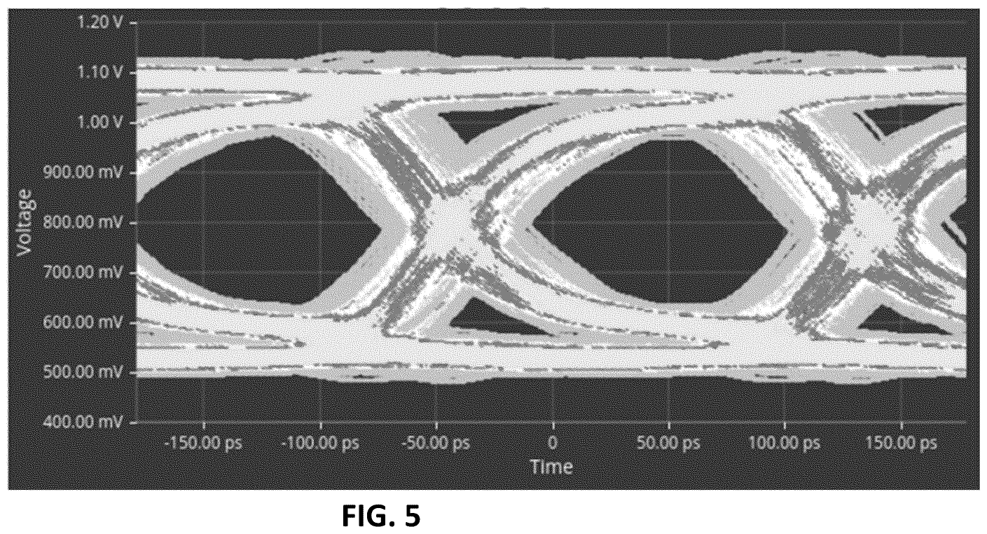

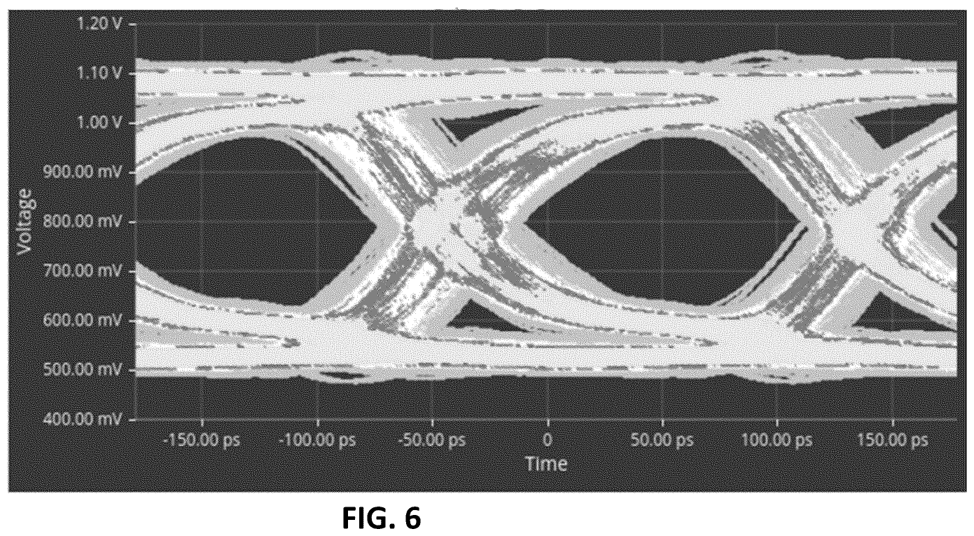

FIGS. 5 and 6 are eye diagrams showing the effects of a Memory DUT operating with optimal DCA register settings and the Memory DUT operating without optimized DCA settings. FIG. 5 shows the output of a Memory DUT before optimal settings were determined, such as by using the series of operations described with reference to FIG. 4. FIG. 6, conversely, shows the output of the Memory DUT after the optimum DCA settings were determined and stored in the mode register, such as the DCA settings register 214 of FIG. 2. In both FIGS. 5 and 6 the eye diagrams illustrate the Memory DUT, which is a DDR5 DRAM DUT operating at a data rate of 5600 MT/s.

Table 1 shows the comparison of DQS and DQ jitter using the proposed methodology and without DCA proving the enhancement of jitter values using the proposed enhanced DCA training methodology.

TABLE 1

| Parameters | Using described DCA | | Without DCA | |
|---|---|---|---|---|
| DQS JITTER | 123.815 | mUI | 144.191 | mUI |
| DQ JITTER | 80.527 | mUI | 93.503 | mUI |
| Eye Width | 479.04 | mUI | 469.74 | mUI |

The foregoing description of the invention has been set merely to illustrate the invention and is not intended to be limiting. Since modifications of the disclosed embodiments incorporating the substance of the invention may occur to person skilled in the art, the invention should be construed to include everything within the scope of the invention.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the disclosed technologies are provided below. An embodiment of the technologies may include one or more, and any combination of, the examples described below.

Example 1 is a test and measurement instrument including one or more test channels to connect to a memory device under test (DUT) and analyze signals generated by the DUT, and one or more processors configured to execute code to cause the DUT to generate a first signal using a first clock setting of the DUT, determine whether a period of the first signal is within a tolerance specification, and perform at least one additional measurement of the DUT when the period of the first signal is within the tolerance specification.

Example 2 is a test and measurement instrument according to Example 1, where the one or more processors are further configured to execute code to, when the period of the first signal using the first clock setting of the DUT is not within the tolerance specification, change the clock setting of the DUT to a subsequent clock setting.

Example 3 is a test and measurement instrument according to Example 1 or Example 2, where the one or more processors are further configured to execute code to determine whether the period of the first signal is within the tolerance specification.

Example 4 is a test and measurement instrument according to any one of Examples 1-3, in which the first clock setting is a set of three clocks each set to a particular setting.

Example 5 is a test and measurement instrument according to any one of Examples 1-4, in which the DUT is a DDR SDRAM, and in which the set of three clocks include an input burst clock, a quarter clock, and a quarter burst clock.

Example 6 is a test and measurement instrument according to any one of Examples 1-5, where the one or more processors are further configured to execute code to store the first clock setting in a DCA register within the DUT.

Example 7 is a test and measurement instrument according to any one of Examples 1-6, where the one or more processors are further configured to execute code to cause the one or more processors to cause the DUT to generate a second signal using the first clock setting of the DUT, determine whether a period of the second signal is within a tolerance specification, and perform at least one additional measurement of the DUT when the period of the second signal is within the tolerance specification.

Example 8 is a test and measurement instrument according to any one of Examples 1-7, in which the first signal is a strobe signal and the second signal is a data signal.

Example 9 is a test and measurement instrument including one or more test channels to connect to a memory device under test (DUT) and analyze signals generated by the DUT, and one or more processors configured to execute code to determine an input burst clock (IBCLK) that satisfies a period tolerance specification; determine a quarter clock (QCLK) that satisfies a duty-cycle tolerance specification, determine a quarter burst clock (QBCLK) that satisfies the duty-cycle tolerance specification, and perform at least one additional measurement of the DUT after the IBCLK, QCLK, and QBCLK have satisfied their respective specifications.

Example 10 is a test and measurement instrument according to Example 9, where determine an input burst clock (IBCLK) that satisfies a period tolerance specification includes include generating a first signal by the DUT using a first IBCLK setting, performing a period test on even and odd cycles of the first signal, and determining whether the period test is within the period tolerance specification.

Example 11 is a test and measurement instrument according to Example 9 or Example 10, where determine an input burst clock (IBCLK) that satisfies a period tolerance specification further including, when the period test is not within the period tolerance specification, modifying the IBCLK setting; performing the period test on even and odd cycles of the first signal using the modified IBCLK setting; and determining whether the period test using the modified IBCLK setting is within the period tolerance specification.

Example 12 is a method of operating a test and measurement instrument to measure a memory device under test (DUT) having controllable DCA registers for an input burst clock (IBCLK), quarter clock (QCLK), and quarter burst clock (QBCLK), the method including initializing values of the IBCLK, QCLK, and QBCLK, and, while maintaining the QCLK and QBCLK at the initialized values, performing a period test on a signal generated by the DUT using present values for IBCLK, QCLK, and QBCLK, and when the period test is not within a tolerance value, repeatedly changing the IBCLK to a subsequent value, and performing the period test on the signal until the period test first satisfies the tolerance value.

Example 13 is the method according to Example 12, further including setting, as an optimized value, the IBCLK to the value that first satisfies the tolerance value.

Example 14 is the method according to Example 12 or Example 13, further including maintaining the IBCLK at the optimized value, maintaining the QBCLK at an initial value, and performing the period test on the signal generated by the DUT using the present values for IBCLK, QCLK, and QBCLK, and when the period test is not within a tolerance value, repeatedly changing the QCLK to a subsequent value, and performing the period test on the signal until the period test first satisfies the tolerance value.

Example 15 is a method according to any one of Examples 12-14, further including setting, as an optimized value, the QCLK to the value that first satisfies the tolerance value.

Example 16 is a method according to any one of Examples 12-15, further including maintaining the IBCLK at the optimized value; maintaining the QCLK at the optimized value, and performing the period test on the signal generated by the DUT using the present values for IBCLK, QCLK, and QBCLK, and when the period test is not within a tolerance value, repeatedly changing the QBCLK to a subsequent value, and performing the period test on the signal until the period test first satisfies the tolerance value.

Example 17 is a method according to any one of Examples 12-16, further including setting, as an optimized value, the QBCLK to the value that first satisfies the tolerance value.

Example 18 is a method according to any one of Examples 12-17, further including storing the optimized values for the IBCLK, QCLK, and QBCLK into the DUT.

Example 19 is a method according to any one of Examples 12-18, further including performing additional tests on the DUT after the optimized values have been stored into the DUT.

Example 20 is a method according to any one of Examples 12-19, in which the additional test includes strobe jitter, data jitter, and data stressed eye tests.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

We claim:

1. A test and measurement instrument, comprising:
one or more test channels to connect to a memory device under test (DUT) and analyze signals generated by the DUT; and
one or more processors configured to execute code to:
cause the DUT to generate a first signal using a first clock setting of the DUT,
determine whether a period of the first signal is within a tolerance specification, and
perform at least one additional measurement of the DUT when the period of the first signal is within the tolerance specification.

2. The test and measurement instrument according to claim 1, wherein the one or more processors are further configured to execute code to, when the period of the first signal using the first clock setting of the DUT is not within the tolerance specification, change the clock setting of the DUT to a subsequent clock setting.

3. The test and measurement instrument according to claim 2, wherein the one or more processors are further configured to execute code to determine whether the period of the first signal is within the tolerance specification.

4. The test and measurement instrument according to claim 1, in which the first clock setting is a set of three clocks each set to a particular setting.

5. The test and measurement instrument according to claim 4, in which the DUT is a DDR SDRAM, and in which the set of three clocks include an input burst clock, a quarter clock, and a quarter burst clock.

6. The test and measurement instrument according to claim 5, wherein the one or more processors are further configured to execute code to store the first clock setting in a DCA register within the DUT.

7. The test and measurement instrument according to claim 1, wherein the one or more processors are further configured to execute code to cause the one or more processors to cause the DUT to:
generate a second signal using the first clock setting of the DUT;
determine whether a period of the second signal is within a tolerance specification; and
perform at least one additional measurement of the DUT when the period of the second signal is within the tolerance specification.

8. The test and measurement instrument according to claim 7, in which the first signal is a strobe signal and the second signal is a data signal.

9. A test and measurement instrument, comprising:
one or more test channels to connect to a memory device under test (DUT) and analyze signals generated by the DUT; and
one or more processors configured to execute code to:
determine an input burst clock (IBCLK) that satisfies a period tolerance specification;
determine a quarter clock (QCLK) that satisfies a duty-cycle tolerance specification;
determine a quarter burst clock (QBCLK) that satisfies the duty-cycle tolerance specification; and
perform at least one additional measurement of the DUT after the IBCLK, QCLK, and QBCLK have satisfied their respective specifications.

10. The test and measurement instrument according to claim 9, wherein determine an input burst clock (IBCLK) that satisfies a period tolerance specification comprises:
generating a first signal by the DUT using a first IBCLK setting;
performing a period test on even and odd cycles of the first signal; and
determining whether the period test is within the period tolerance specification.

11. The test and measurement instrument according to claim 10, wherein determine an input burst clock (IBCLK) that satisfies a period tolerance specification further comprises:
when the period test is not within the period tolerance specification:
modifying the IBCLK setting;
performing the period test on even and odd cycles of the first signal using the modified IBCLK setting; and
determining whether the period test using the modified IBCLK setting is within the period tolerance specification.

12. A method of operating a test and measurement instrument to measure a memory device under test (DUT) having controllable DCA registers for an input burst clock (IBCLK), quarter clock (QCLK), and quarter burst clock (QBCLK), the method comprising:
initializing values of the IBCLK, QCLK, and QBCLK; and
while maintaining the QCLK and QBCLK at the initialized values:
performing a period test on a signal generated by the DUT using present values for IBCLK, QCLK, and QBCLK, and
when the period test is not within a tolerance value:
repeatedly changing the IBCLK to a subsequent value, and
performing the period test on the signal until the period test first satisfies the tolerance value.

13. The method according to claim 12, further comprising setting, as an optimized value, the IBCLK to the value that first satisfies the tolerance value.

14. The method according to claim 13, further comprising:
maintaining the IBCLK at the optimized value;
maintaining the QBCLK at an initial value; and
performing the period test on the signal generated by the DUT using the present values for IBCLK, QCLK, and QBCLK, and
when the period test is not within a tolerance value:
repeatedly changing the QCLK to a subsequent value, and
performing the period test on the signal until the period test first satisfies the tolerance value.

15. The method according to claim 14, further comprising setting, as an optimized value, the QCLK to the value that first satisfies the tolerance value.

16. The method according to claim 15, further comprising:
maintaining the IBCLK at the optimized value;
maintaining the QCLK at the optimized value; and
performing the period test on the signal generated by the DUT using the present values for IBCLK, QCLK, and QBCLK, and
when the period test is not within a tolerance value:
repeatedly changing the QBCLK to a subsequent value, and
performing the period test on the signal until the period test first satisfies the tolerance value.

17. The method according to claim 16, further comprising setting, as an optimized value, the QBCLK to the value that first satisfies the tolerance value.

18. The method according to claim 16, further comprising storing the optimized values for the IBCLK, QCLK, and QBCLK into the DUT.

19. The method according to claim 18, further comprising performing additional tests on the DUT after the optimized values have been stored into the DUT.

20. The method according to claim 19, in which the additional test includes strobe jitter, data jitter, and data stressed eye tests.
